(19) United States
(12) Patent Application Publication
(10) Pub. No.: US 2019/0363690 A1
(43) Pub. Date: Nov. 28, 2019

(54) Low Noise Amplifier with Tunable Bypass Match

(71) Applicant: pSemi Corporation, San Diego, CA (US)

(72) Inventors: Joseph Golat, Crystal Lake, IL (US); David Kovac, Arlington Heights, IL (US); Emre Ayranci, Costa Mesa, CA (US); Miles Sanner, San Diego, CA (US)

(21) Appl. No.: 16/201,777

(22) Filed: Nov. 27, 2018

Related U.S. Application Data
(63) Continuation-in-part of application No. 15/728,314, filed on Oct. 9, 2017, now Pat. No. 10,177,715.

(51) Int. Cl. H03G 3/30; H03F 3/19

(52) U.S. Cl. CPC H03G 3/3036; H03F 3/19; H03F 2200/294; H03G 2201/307; H03F 2200/222; H03G 2201/103; H03F 2200/451

(57) ABSTRACT

A front end module (FEM) and associated method for receiving signals in a front end module are disclosed. Some embodiments of the FEM have three inputs. The FEM can process the input signals in one of three bypass modes. In bypass modes, switchable tank circuits provide a high impedance to isolate active components from the bypass path. This improves the input return loss in the passive bypass mode and thus improves the performance of the passive bypass mode by allowing the use of LNAs without an input switch. In the active gain mode, one of a plurality of signals are amplified by one of an equal number of amplifiers coupled to the FEM output. Accordingly, the FEM can output signals applied to any one of the FEM inputs in bypass mode, or an amplified version of one of the input signals. In some embodiments, the FEM has only one input and one LNA. In such embodiments, an output selector switch selects between a bypass path and a gain path.

### CROSS-REFERENCE TO RELATED APPLICATIONS—CLAIM OF PRIORITY

This application is a continuation-in-part of, and claims the benefit of priority under 35 USC § 120 of, commonly assigned and co-pending prior U.S. application Ser. No. 15/728,314, filed Oct. 9, 2017, “Front End Module with Input Match Configurability”, the disclosure of which is incorporated herein by reference in its entirety.

### BACKGROUND

### (1) Technical Field

This disclosure relates to transceivers, and more specifically to methods and apparatus for selecting between bypass modes and active gain modes in a receiver.

(2) Background

The front-end of a communications receiver typically includes an amplifier, such as a low-noise amplifier (“LNA”). The LNA is responsible for providing the first-stage amplification to a signal received by the communications receiver. The operational specifications of the LNA are very important to the overall quality of the communications receiver. Any noise or distortion introduced by the LNA will cause a degradation in the overall receiver performance. That is, the sensitivity of a receiver is in large part determined by the quality of the front-end, and in particular, by the quality of the LNA. The sensitivity of the receiver, in turn, determines the amount of information that can be transmitted in a predetermined amount of time (e.g., the bit rate in bits per second) at a predetermined bit error rate.

The quality of an LNA often times depends upon parameters such as noise figure (NF), input impedance match, output impedance match, gain and linearity. These characteristics determine the amount of distortion imposed on signals received through the front-end, how strong a signal needs to be and the signal-to-interference-plus-noise ratio (SINR) required to recover information transmitted at a particular data rate. Demand continues to grow for ever higher data rates. High data rates require greater accuracy in the demodulation of signals received by today's receivers, making characteristics like NF, input impedance match and output impedance match important parameters to be controlled.

Some receivers are capable of receiving signals from one of several sources. There are significant challenges to designing a high performance LNA for use in a radio frequency (RF) front end module (FEM) that can select between several sources. In some cases, the challenge is made greater by the need to operate in several bands spread over a wide frequency range. In some such instances, an RF FEM is provided which has several input ports. Each port is dedicated to receiving signals within one frequency band from one of several sources. In some such cases, it is common for the receiver FEM to have a selector switch for selecting which input is to be coupled to the LNA. In addition, there may be several gain paths that the input can take. The selector switch can be controlled either directly by a user or by software to select both the gain path and the particular frequency band.

FIG. 1 is a simplified illustration of an FEM 100. The FEM 100 includes an LNA integrated circuit (LNAIC) 101 having several inputs 102, 104, 106. In some cases, a “solder ball” is used on the LNAIC 101 to provide a point of electrical contact between the LNAIC 101 (and in particular each input 102, 104, 106) and one or more signal sources external to the LNAIC 101. In the particular case shown in FIG. 1, each input 102, 104, 106 receives signals from a corresponding one of several surface acoustic wave (SAW) filters 108, 110, 112 within the FEM 100. Each SAW filter 108, 110, 112 is tuned to the frequency band of the corresponding input 102, 104, 106. A double pole, three throw input selector switch 114 provides a means by which the inputs can be connected to one of two signal paths 115, 117.

The first signal path 115 is a high gain path that couples one of the SAW filters 108, 110, 112 to an input inductor 116 that resides outside the LNAIC 101. The input inductor 116 is coupled to the LNAIC 101 through two contacts 118, 120. The signal routed through the input inductor 116 and coupled back to the LNAIC 101 by the second contact 120. The signal is coupled from the second contact 120 to the input of an LNA 122 within the LNAIC 101. The output of the LNA 122 is coupled to a switched attenuator 124. The attenuator 124 provides additional control of the gain of the FEM 100. The output of the attenuator 124 is coupled to a high gain path input 125 of a single pole, double throw output selector switch 126. The output of the switch 126 is coupled to the output of the FEM 100. By selecting the high gain path input 125, the signal that traverses the high gain path 115 is coupled to the output of the FEM 100.

The second signal path 117 is a low gain path. The low gain path 117 couples the second output of the input selector switch 114 to a second switched attenuator 128. The attenuator 128 reduces the signal level before coupling the signal to a single pole, double throw bypass switch 130. The switch 130 selects between a bypass path 132 directly to the output selector switch 126 and a low gain path 134 to the input inductor 116 and LNA input. Selecting the low gain path 117 through the input selector switch 114 and the bypass output through the bypass switch 130 provides a passive bypass path having a gain<1. Alternatively, an active low gain path 134 can be selected through the FEM 100 that uses the attenuator 128 to attenuate the signal prior to amplification by the LNA 122 and uses attenuator 124 to attenuate the signal after amplification by the LNA 122.

The FEM 100 of FIG. 1 has at least two limitations. The first limitation is that the input selector switch 114 adds attenuation to the high gain path 115 prior to amplification by the LNA 122, reducing the noise figure of the high gain path. That is, when a signal is attenuated before amplification, the signal to noise level goes down and the NF goes up.

The second limitation is that the LNA 122 must simultaneously be optimized for operation in each frequency band. Since the range of frequencies for which the FEM 100 must operate can be relatively broad, it may be difficult to ensure optimum operation across the full spectrum of operating frequencies.

Accordingly, there is currently a need for a method and apparatus that allows an FEM to receive multiple inputs, select between the multiple inputs (including combinations of inputs) and select between active gain or passive bypass modes. Furthermore, it would be desirable to have an FEM with a low impedance path between inputs and the LNA in at least the high gain modes to help maintain best noise figure. The present disclosure presents a method and apparatus that meets this need.

### SUMMARY

A front end module (FEM) and associated method for receiving signals in a FEM are disclosed. Some embodiments of the FEM has a low noise amplifier integrated circuit (LNAIC). The LNAIC has connection points through which signals can be coupled between the LNAIC and the other components of the FEM. The FEM can process the input signals in one of a plurality of bypass modes or in one of a plurality of active gain modes.

In some embodiments, when operating in one of the bypass modes, a signal applied to the FEM through one of several inputs is coupled directly to an FEM output through an output selector switch. The input to each LNA is isolated from the FEM output by a corresponding switchable tank circuit. The corresponding tank circuit comprises an inductor associated with a corresponding capacitor switch and a corresponding capacitance. The capacitor switch and the capacitor are coupled in series. The series combination of capacitance and capacitor switch is coupled in parallel to the corresponding inductor. In bypass mode, all of the LNAs are turned off and the capacitor switch within each tank circuit corresponding to the LNAs is closed. Closing the capacitor switch creates a resonant circuit between the inductor and a corresponding capacitance. Each tank circuit provides a relatively high impedance between the corresponding FEM input and the corresponding input of the LNA at the frequency of the input signal to be output by the FEM.

In some embodiments, in a first active gain mode, one of the LNAs is turned on and the associated capacitor switch is opened. The capacitor switches associated with the other LNAs are closed to form a high impedance tank circuit at the input of the LNAs that are turned off. The inductor that is in parallel with the open capacitor switch (i.e., the inductor associated with the LNA that is turned on) provides an input inductance to the operational LNA. The outputs of each LNA are coupled together. The outputs of the LNAs (only one of which is typically operational at a time) are coupled through an output capacitor to a switched attenuator. The output of the attenuator is coupled to the FEM output selector switch. Accordingly, the FEM can output signals applied to any one of several inputs that bypasses the LNAs in a bypass mode, or an amplified input signal in one of the several selectable active gain modes. In some embodiments, the FEM has only one input and one LNA. In such embodiments, the output selector switch selects between the bypass path and the gain path.

In some embodiments, the FEM comprises a gain/bypass circuit. In some such embodiments, the gain/bypass circuit comprises a low noise amplifier (LNA), a matching network, a bypass input switch, a bypass output switch, and a gain mode output switch. The matching network is tuned such that the input impedance seen at the input to the gain/bypass circuit, when operating in bypass mode, is within a desired tolerance with respect to the impedance seen at the gain/bypass circuit input when operating in gain mode. That is, depending upon the performance requirements of the FEM, the matching network can be finely tuned to make the input impedance of the gain/bypass circuit, when operating in bypass mode, closely match the input impedance when operating in gain mode. How closely the input impedances match may be determined by a desired tolerance established for the difference.

In some embodiments, the impedance of the matching network can be tuned for particular operating frequencies to optimize the difference between: (1) the impedance seen at the gain/bypass circuit input during bypass mode at a particular desired operating frequency; and (2) the impedance seen at the gain/bypass circuit input during gain mode at the particular desired operating frequency. In some embodiments, a control signal coupled to the matching network changes the impedance of the matching network to tune the impedance for the desired frequency or band within the operating frequency range.

In some embodiments, the gain/bypass circuit further comprises a variable attenuator at the output of the matching network.

In yet other embodiments, a matching network shunt switch is coupled between the output of the matching network and ground. A gain mode output switch is closed, a gain/bypass input switch is closed, a bypass output switch opened and a matching network shunt switch is closed during gain mode. Accordingly, the input of the LNA is coupled to the input of the matching network. The output of the matching network is shunted to ground. The matching network is tuned for one of a plurality of operating frequencies/bands. As a result, the matching network can be used to reduce any differences in the input impedance seen at the input to the FEM when the FEM is operated at different operating frequencies/frequency bands.

In other embodiments, the FEM comprises a plurality of gain/bypass circuits. In some such embodiments, selectively opening and closing the bypass output switch and a gain mode output switch in each gain/bypass circuit allows the outputs of each gain/bypass circuit to be combined at the output of the FEM. In some embodiments, the components of a gain/bypass circuit are fabricated on a single die having one connection terminal coupled to the gain/bypass circuit and one output terminal coupled to an FEM output. Several such gain/bypass circuits may be mounted on a common substrate and packaged together within an FEM.

The details of one or more embodiments of the disclosed method and apparatus are set forth in the accompanying drawings and the description below. Other features, objects, and advantages of the invention will be apparent from the description and drawings, and from the claims.

### DESCRIPTION OF THE DRAWINGS

FIG. 1 is a simplified illustration of an FEM having several inputs.

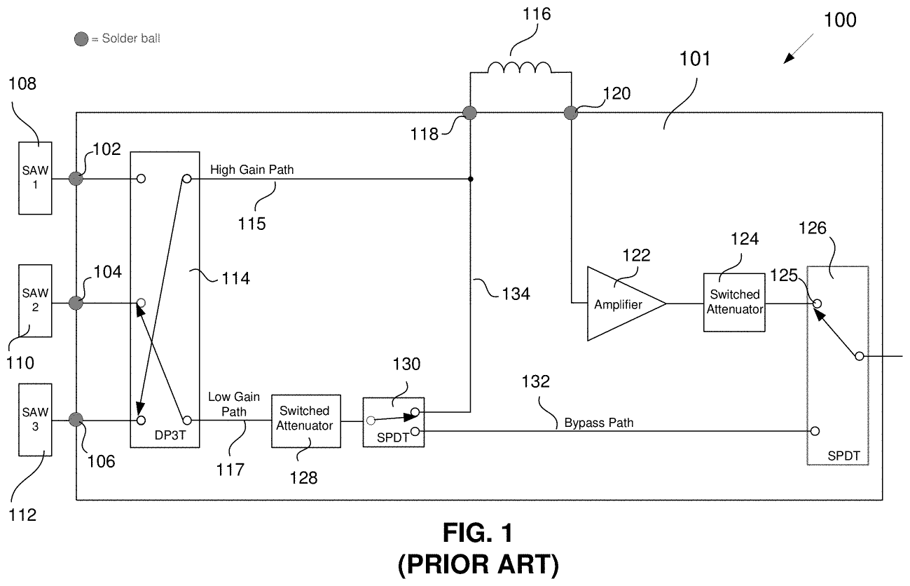

FIG. 2 is a simplified electrical schematic illustrating an FEM and associated external components in accordance with some embodiments of the disclosed method and apparatus.

FIG. 3 is an illustration of an alternative embodiment, in which a second capacitor switch and capacitor are provided in parallel with the input inductor.

FIG. 4 is a simplified schematic of one embodiment of an LNA that may be used to implement the LNAs shown in FIG. 2 and FIG. 3.

FIG. 5 is an illustration of three LNAs coupled together at their outputs.

FIG. 6 shows the three LNAs of FIG. 5 integrated into an FEM.

FIG. 7 is a simplified schematic of an FEM and associated external tank circuits and input inductor.

FIG. 8 is a simplified schematic of a selector switch.

FIG. 9 is a flow diagram of a method in accordance with one disclosed embodiment.

FIG. 10 is a flow diagram of a method in accordance with the disclosed embodiment in which at least one of the LNAs is active.

FIG. 11 is a flow diagram of a method in accordance with the disclosed embodiment in which the FEM shown in FIG. 7 is used.

FIG. 12 is a simplified schematic of an FEM 1200 having a plurality of gain/bypass circuits.

FIG. 13 is a simplified schematic of an FEM similar to that of FIG. 12, however, a matching network shunt switch is provided at the output of the matching network.

FIG. 14 is a simplified schematic of yet another embodiment of the disclosed apparatus in which a matching network comprises shunt capacitors placed in parallel.

Like reference numbers and designations in the various drawings indicate like elements.

### DETAILED DESCRIPTION

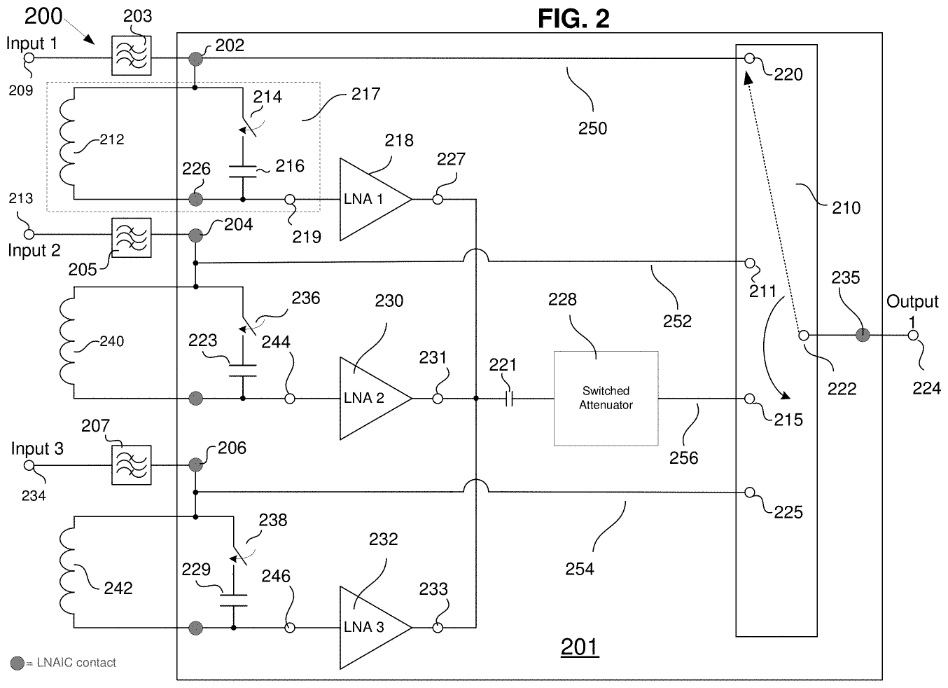

FIG. 2 is a simplified electrical schematic illustrating a front end module (FEM) 200 comprising a low noise amplifier integrated circuit (LNAIC) 201 and associated external components in accordance with some embodiments of the disclosed method and apparatus. In the embodiment shown in FIG. 2, the LNAIC 201 has three input connection points 202, 204, 206. In some embodiments, these are external connection points 202, 204, 206 implemented as solder balls, wirebonds, etc. on the LNAIC 201 that provide points of contact through which input signals can be coupled to the LNAIC 201 from external devices (such as filters 203, 205, 207, which in some embodiments may be SAW filters either within the FEM 200 or external to the FEM 200). In other embodiments in which the LNAIC 201 is integrated into a larger component of a receiver or other device, the connection points 202, 204, 206 are merely points that connect to other components within the receiver or other device.

The FEM 200 can process the input signals in one of several bypass modes or active modes. In the example shown in FIG. 2, the FEM 200 has three inputs 209, 213, 234. The LNAIC 201 has three input connection points 202, 204, 206 and associated LNAs 218, 230, 232. Accordingly, there are up to three possible active gain modes and three possible bypass modes. However, in other embodiments, any number of inputs and associated LNAs can be provided. Each such input and associated LNA can be associated with a corresponding bypass mode. In the example shown in FIG. 2, in the first bypass mode, signals applied to the LNAIC 201 through the first input connection point 202 (i.e., input 1) are coupled directly to a contact 224 at the FEM output through an output selector switch 210. In some such embodiments, the output selector switch 210 selects between one of three bypass paths 250, 252, 254 and the gain path 256. In order to remove the load of the LNA 218, 230, 232 from the input connection point 202, 204, 206, a tank circuit is created by closing a capacitor switch 214, 236, 238 to place a capacitance 216, 223, 229 in parallel with an associated inductance 212, 240, 242. In some embodiments, the associated inductances 212, 240, 242 are within the FEM 200, but outside the LNAIC 201. In some embodiments, the capacitance 216, 223, 229 is provided by a capacitor. In other embodiments, the capacitance is provided by any other structure that has operational capacitance (i.e., that establishes a resonant tank circuit to establish a relatively high impedance at the operation frequency when placed in parallel with the associated inductance 212, 240, 242). In some embodiments, the capacitor switches 214, 236, 238 and the capacitances 216, 223, 229 are within the LNAIC 201. The tank circuit provides a relatively high impedance between a corresponding input connection point 202, 204, 206 and an associated LNA 218, 230, 232 when an associated capacitor switch 214, 236, 238 is closed. In each of the bypass modes, all of the capacitor switches 214, 236, 238 are closed to isolate the LNA inputs from the FEM inputs. In each of the gain modes, all but one of the capacitor switches 214, 236, 238 are closed. Opening one of the capacitor switches 214, 236, 238 allows the associated inductor 212, 240, 242 to be used as an input inductance to the associated LNA 218, 230, 232. In some embodiments, more than one LNA 218, 230, 232 may be active. In such cases, each capacitor switch 214, 236, 238 associated with an active LNA 218, 230, 232 would be open. Having more than one LNA 218, 230, 232 active at a time would require the architecture to be designed to sum the signals and handle the associated changes in the input and output impedances. For example, in some embodiments, additional impedance matching circuits (not shown) could be coupled to the input and/or output by switches that are activated when more than one LNA 218, 230, 232 is active.

In some embodiments, the outputs from each of the three LNAs 218, 230, 232 are coupled to a capacitor 221. The capacitor 221 is coupled to a variable attenuator (such as a switched attenuator 228). The output of the attenuator 228 is coupled to the contact 224 at the FEM output through the output selection switch 210 when the switch 210 is in the gain mode position. Accordingly, the FEM 200 can output signals applied to any one of the input connection points 202, 204, 206 in one of the bypass modes, or from one of the LNAs 218, 230, 232 in one of the gain modes.

In some embodiments, the LNAIC 201 has only one input connection point 202 and one LNA 218. In alternative embodiments, the FEM 200 can operate in a combined gain mode in which inputs from more than one LNA are combined prior to the FEM output 224.

A more detailed discussion of the signal path through the FEM 200 in bypass mode is provided first, followed by a more detailed discussion of the signal path through the FEM 200 in the gain mode. The signal paths for input signals applied to each of the three input connection points 202, 204, 206 are essentially the same. Therefore, for the sake of simplicity, only the signal path from the first input connection point 202 (i.e., the first input) to the output of the FEM 200 is discussed in detail.

Input signals enter the FEM 200 through an input 1 coupled to the input connection point 202 of the LNAIC 201. The contact 202 also provides a point of contact to components external to the LNAIC 201. In particular, in some embodiments, the input connection point 202 provides a connection point to a first terminal of the input inductor 212. A first terminal of the capacitor switch 214 that resides within the LNAIC 201 is also coupled to the input connection point 202. Alternatively, a separate inductance connection point (not shown) can be provided on the LNAIC 201. A second terminal of the switch 214 is coupled to a first terminal of the capacitor 216. A second terminal of the capacitor 216 is coupled to an inductance connection point 226. A second terminal of the inductor 212 is coupled to the LNAIC 201 through the inductance connection point 226. In some embodiments, the input inductor 212 resides outside the LNAIC 201 and is coupled to the LNAIC 201 through input connection points 202, and the inductance connection point 226. The capacitor 216 and the capacitor switch 214 reside within the LNAIC 201. In other embodiments, all of the components 212, 214, 216 reside within the LNAIC 201. In yet another embodiment, all of the components 212, 214, 216 reside outside the LNAIC 201.

In bypass mode, the switch 214 is closed. Closing the switch 214 places the capacitor 216 in parallel with the input inductor 212. Accordingly, the input inductor 212, capacitor switch 214 and capacitor 216 form a switchable tank circuit 217. The value of the capacitor 216 is selected such that for frequencies within the operational range of the first input, the impedance of the tank circuit 217 (i.e., with the switch 214 closed) is relatively high with respect to the characteristic impedance of the system in which the FEM 200 resides. As is discussed further below, the value of the input inductor 212 is selected to provide a proper input impedance match for the LNA 218 with the switch 214 open in active gain mode.

For some embodiments in which the characteristic impedance of a receiver is 50 ohms, the impedance that is presented by the parallel tank circuit 217 may be above 1,000 ohms. In some embodiments, the tank circuit 217 can be tuned to resonate at the center frequency of the first input. In such cases, depending upon the Q of the tank circuit, the impedance presented by the tank circuit 217 can be much greater. It should be noted that the higher the Q of the tank circuit, the higher the impedance at resonance and the sharper the slope of the impedance curve near the resonant frequency. While high impedance is desirable to isolate the load at the output of the FEM 200 from the capacitive loading that would otherwise be imposed the LNA input, it may be advantageous to reduce the Q of the tank circuit 217 in order to provide a flatter frequency response in the operational frequency range. Alternatively, the frequency response of the tank circuit 217 over the operational range will be flatter if the tank circuit 217 is tuned to resonate at a frequency that is offset from the center of the operational frequency range. It will be clear to those skilled in the art that there is a tradeoff between having a relatively high impedance in the operational frequency range and attaining a desirable frequency response over the operational frequency range.

In some embodiments, the input connection point 202 is also coupled to a first input 220 of the output selector switch 210. In some embodiments, the output selector switch is a single pole, four throw output selector switch 210. Accordingly, the output 222 of the switch 210 can be selectively coupled to one of a plurality of inputs 220, 211, 215, 225 to the switch. In addition to closing the switch 214 in bypass mode, the first input 220 of the output selector switch 210 is selected (i.e., the first input 220 of the switch 210 is coupled to the output 222 of the switch 210). Accordingly, a path from the input connection point 202 to an LNAIC output connection point 235, and then on to a contact 224 at the output of the FEM 200 allows the LNA 218 to be bypassed, providing a passive bypass path for signals input through the FEM 200. The tank circuit 217 created when the switch 214 is closed provides a high impedance between the input connection point 202 and the LNA input 219 to reduce the effect of the LNA (e.g., loading by the input of the LNA 218) on the signals during passive bypass mode.

In a first of the active gain modes, the capacitor switch 214 is opened. In addition, the output selector switch 210 is set to select the third switch input 215. That is, the output of the attenuator 228 will be coupled through the switch 210 to the FEM output contact 224. With the capacitor switch 214 open, the signal applied to input 1 209 of the FEM 200 through the input connection point 202 of the LNAIC 201 is coupled through the input inductor 212 to the inductance connection point 226. The inductance connection point 226 is coupled to the LNA input 219. The inductance of the input inductor 212 is selected to provide a good input impedance match between the input signal source and the LNA 218. Therefore, with the capacitor switch 214 open, power will be efficiently coupled to the input of the LNA 218.

The output 227 of the LNA 218 is coupled through a capacitor 221 to the switched attenuator 228 within the LNAIC 201. In the embodiment shown in FIG. 2, in which there are three LNAs 218, 230, 232, the LNA output 227 is also coupled to the outputs 231, 233 of the other two LNAs 230, 232. However, in some embodiments of the disclosed method and apparatus, only one LNA 218, 230, 232 is active at a time in the active gain mode. The other LNAs are inactive (i.e., turned off) and the associated capacitor switch 214, 236, 238 is closed to create a high impedance to the input of the other LNAs 230, 232.

In some embodiments, the attenuation provided by the attenuator 228 is adjustable. Accordingly, the gain provided in the active gain mode can be controlled. In addition, in some embodiments, the gain of the amplifiers 218, 230, 232 can be controlled to further control the overall gain in the active gain mode. In the active gain mode, only one of the capacitor switches 214, 236, 238 are open to provide a signal path through the associated inductor 212, 240, 242 to the input 219, 244, 246 of the associated LNA 218, 230, 232. However, in an alternative embodiment, it is possible to have only signals associated with two or more of the inputs present in the output signal. In such cases, the capacitor switch 214, 236, 238 associated with those inputs that are not desired can be closed to increase the impedance presented to those inputs. In addition, further switching or gain control can be implemented within the LNAs 218, 230, 232.

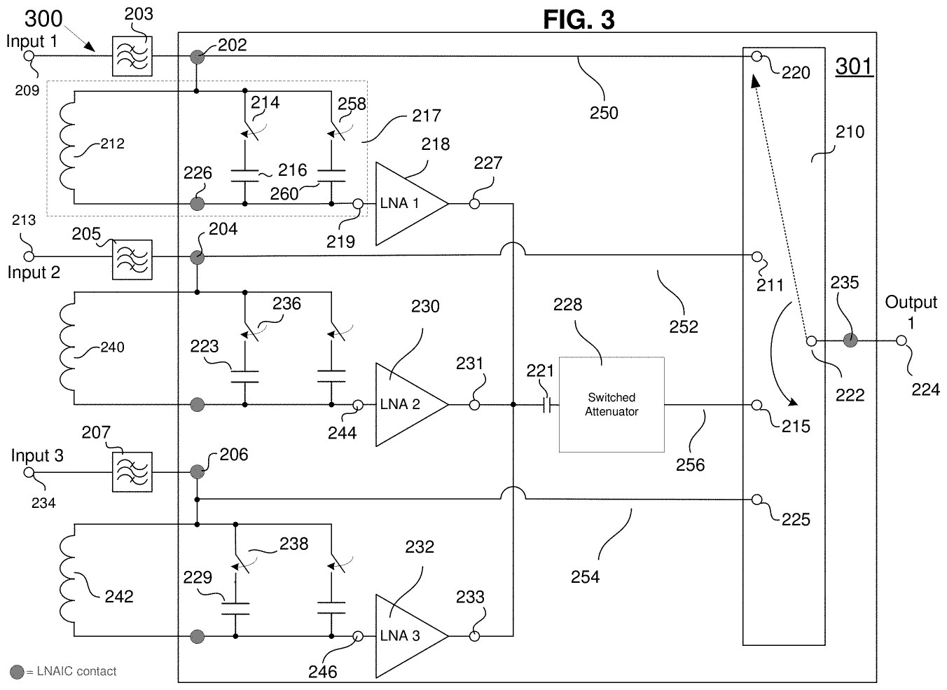

FIG. 3 is an illustration of an alternative embodiment of an FEM 300 and LNAIC 301, in which a second series combination of capacitor switch 258 associated with a corresponding capacitor 260 are provided in parallel with the input inductor 212. Accordingly, if a first frequency is likely to be provided through input 2 when the second LNA 230 is active, the resonant frequency of the tank circuit 217 corresponding to inactive LNA 218 can be set to have a high impedance at that frequency by closing the first capacitor switch 214. If a second different frequency is provided through input 3 when the third LNA 232 is active, the resonant frequency of the tank circuit 217 can be adjusted to optimize the operation for the second frequency by closing the second capacitor switch 258. Likewise, an additional series combination of capacitor switch and capacitor can be placed in parallel with each of the other inductors 240, 242. It should be understood that the number of series combinations of capacitor switch and corresponding capacitor placed in parallel with each inductor can be selected to achieve a desired flexibility for embodiments in which different frequencies are presented (i.e., in order to adjust the resonant frequency of the tank circuit at the input of each LNA to optimize the operation for the input frequency presented at the inputs).

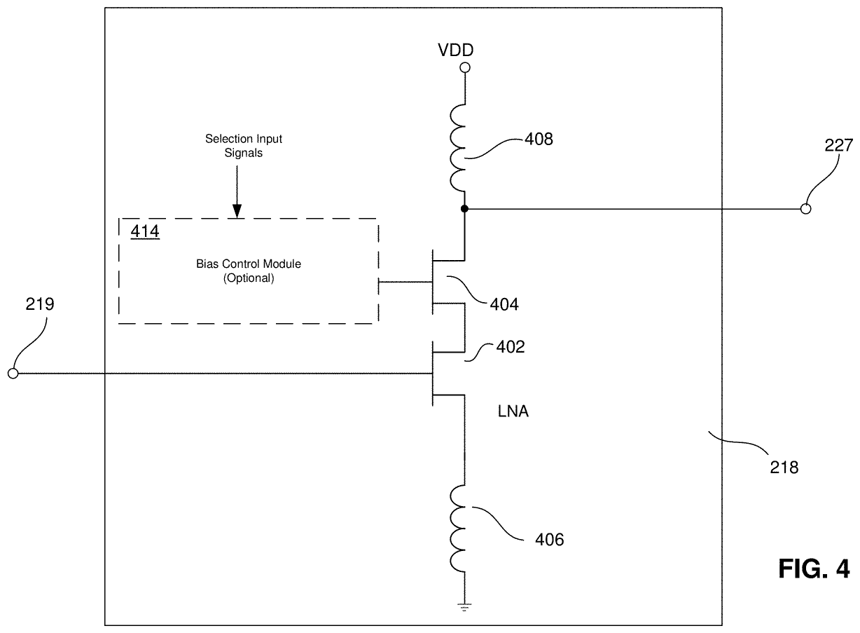

FIG. 4 is a simplified schematic of one embodiment of an LNA 218 that may be used to implement the LNAs 218, 230, 232 shown in FIG. 2 and FIG. 3. The LNA 218 includes an input transistor 402 and an output transistor 404. In some embodiments, the input and output transistors 402, 404 are field effect transistors (FETs). The input 219 to the LNA is coupled to the gate of the input FET 402. The drain of the input FET 402 is coupled to the source of the output FET 404. The source of the input FET 402 is coupled to a first terminal of a degeneration inductor 406. A second terminal of the degeneration inductor 406 is coupled to ground. A load inductor 408 is coupled between the drain of the output FET 404 and a voltage source.

In some embodiments, a bias control module 414 controls a bias voltage that is coupled to the gate of the output FET 404. The bias voltage can be used to turn the LNA 218 on and off. In some cases, the LNA 218 is turned off when the input associated with the LNA 218 is in bypass mode (i.e., when the capacitor switch 214 is closed and the output selector switch 210 couples the input associated with the LNA 218 to the output of the FEM 200). In addition, in some embodiments, the LNA 218 may be turned off if the input associated with that LNA is not desired at the output of the FEM 200. Furthermore, in some embodiments, the bias voltage can also be used to control the gain of the LNA 218 when the FEM 200 is not in bypass mode (i.e., when the FEM 200 is in active gain mode). Still further, the bias control module 414 can be used to control the input FET 402.

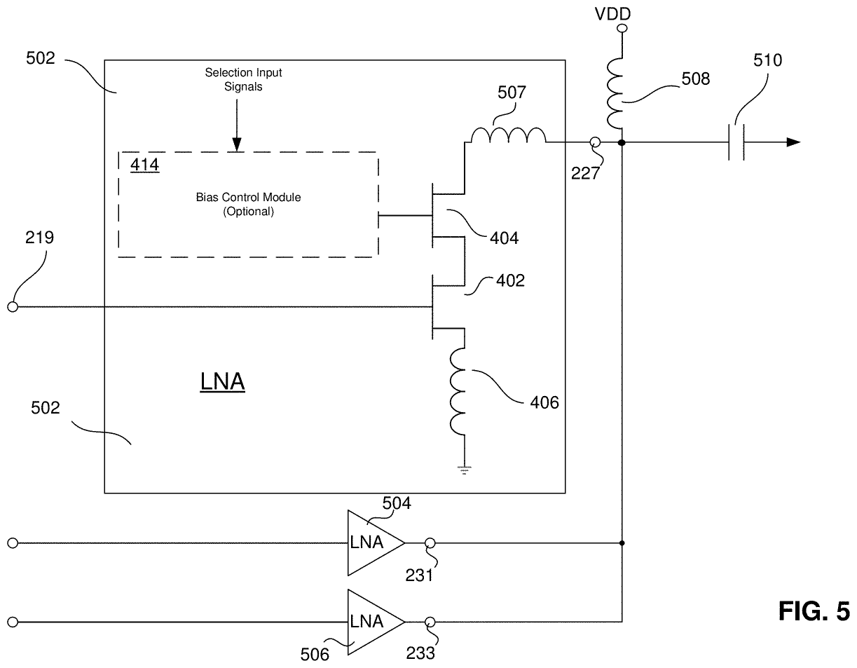

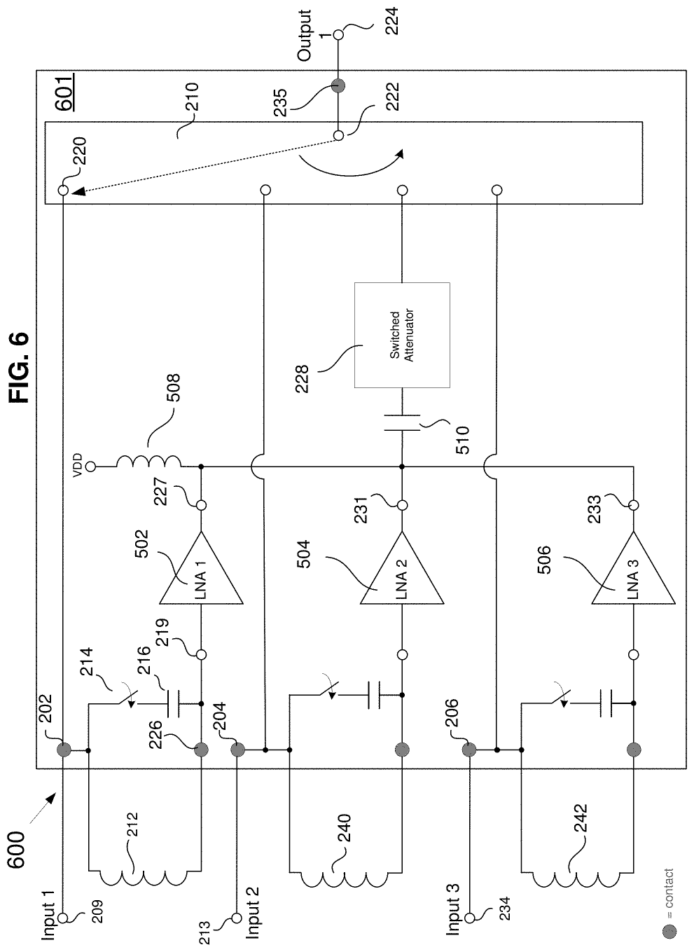

FIG. 5 is an illustration of three LNAs 502, 504, 506, coupled together at their outputs 227, 231, 233. FIG. 6 shows the three LNAs 502, 504, 506 integrated into an LNAIC 601 of an FEM 600. FIG. 5 shows one of the LNAs 502 in greater detail. In some embodiments, the other two LNAs 231, 233 are similar. Therefore, for the sake of simplicity, only LNA 502 is discussed in detail. In some embodiments in which several LNAs 502, 504, 506 are directly coupled at their outputs 227, 231, 233 the parasitic capacitance of the output FETs 404 in the LNAs 502, 504, 506 can shift the output impedance of the FEM 200, creating an output impedance mismatch. In some such cases, an inductance 507 coupled to the drain of the output FET 404 can offset the parasitic capacitance of the output FET 404.

Accordingly, coupling the outputs 227, 231, 233 of several such LNAs 502, 504, 506 together has a minimal adverse effect on the output impedance match of the FEM 600. In the embodiment shown in FIG. 6, the inductance 508 is within the LNAIC 601. In some embodiments, the inductance 508 can be provided by the routing inductance of the conductive path between the drain of the FET 404 and the point at which the outputs from each LNA 502, 504, 506 are combined. In other embodiments, an inductor 508 is placed outside the LNAIC 601. Likewise, the output capacitor 510 can be either within the LNAIC 601 or outside the LNAIC 601.

In some embodiments, one or more of the LNAs 502, 504, 506 are implemented using multiple amplifier legs, as is disclosed in copending U.S. patent application Ser. No. 15/272,103, entitled “LNA with Programmable Linearity”, U.S. patent application Ser. No. 15/479,173, entitled “Optimized Multi Gain LNA Enabling Low Current and High Linearity Including Highly Linear Active Bypass” and U.S. patent application Ser. No. 15/430,332, entitled “Programmable Optimized Band Switching LNA for Operation in Multiple Narrow-Band Frequency Ranges”, each of which is incorporated by reference. In addition, other LNA configurations and embodiments can be used in accordance with the present method and apparatus. Furthermore, the capacitors 216, 260 (see FIG. 3) can be implemented at digitally tunable capacitors, such as for example, disclosed in U.S. Pat. No. 9,024,700 entitled “Method and apparatus for use in digitally tuning a capacitor in an integrated circuit device”.

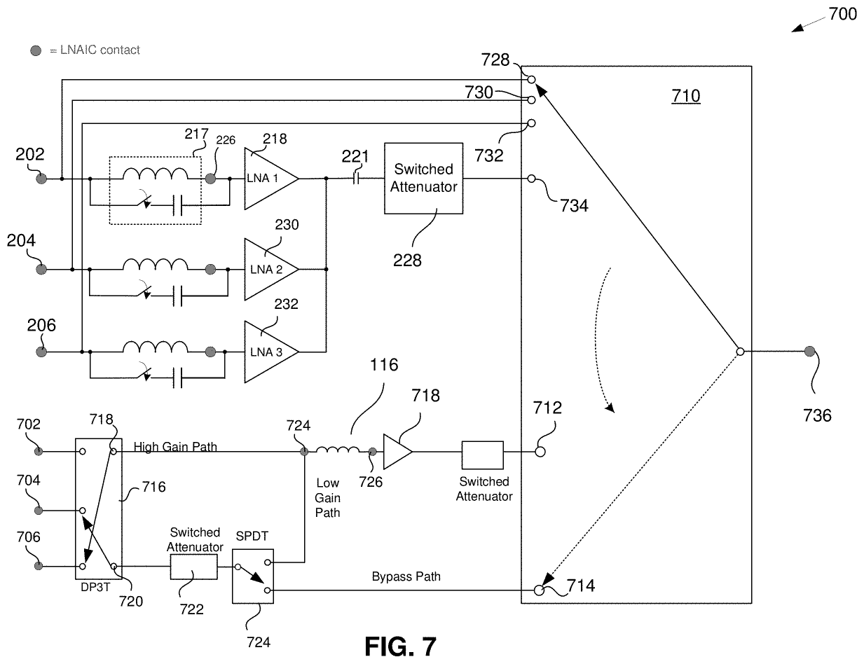

FIG. 7 is a simplified schematic of an FEM 700 having an LNAIC and associated external input inductor 116. The LNAIC has input connection points 202, 204, 206, 702, 704, 706 for receiving six input signals. Three of the input signals are coupled to the input connection points 202, 204, 206 that are in turn coupled to one of three respective tank circuits 217. These three input connection points 202, 204, 206 are also coupled to inputs to an output selector switch 710. The tank circuits 217 are each coupled between a respective one of the three input connection points 202, 204, 206 and a respective one of three LNAs 218, 230, 232. The outputs of the three LNAs 218, 230, 232 are coupled together. The combined output of the LNAs 218, 230, 232 is coupled through an output capacitor 221 to a switched attenuator 228. The output of the switched attenuator 228 is coupled to an input to the output selector switch 710. Accordingly, in similar fashion to that of the FEM 200 discussed above with respect to FIG. 2 and FIG. 3, the FEM 700 can select between three bypass modes and an active gain mode in which the outputs of one of the three LNAs 218, 230, 232 is output through the output select switch 710.

In addition, the output selector switch 710 has a fifth and sixth input 712, 714. The fifth input 712 is a high/low gain input. The high/low gain input provides either a high gain or low gain path to the output of the FEM 700 for one of the inputs applied to the input contacts 702, 704, 706. A high/low gain switch 716 is implemented in one embodiment as a double-pole, three-throw switch 716. The high/low gain switch 716 has three inputs that can each be switchably connected to a first output or a second output of the switch 716. In some embodiments, only one of the two outputs is active at any one time. If one of the input contacts 702, 704, 706 is coupled through the switch 716 to the first output 717, the signals applied to that input will be coupled to an LNA 718 through an input inductor 116. Accordingly, if the output selector switch 710 is set to select the input 712, then a high gain path will be established through the FEM 700 for signals applied to the input contact 702, 704, 706 selected by the input switch 716.

Alternatively, if one of the contacts 702, 704, 706 is selected by the input switch 716 to be output on the second output 720, then the signal applied to that contact 702, 704, 706 is coupled to a switched attenuator 722. The output of the attenuator 722 is coupled to a single-pole, double-throw (SPDT) switch 724. The first output of the SPDT switch 724 is coupled to the input inductor 116 that feeds the input of the LNA 718. Accordingly, if the output selector switch is set to select the fifth input 712, a low gain path is established between the input contact 702, 704, 706 selected by the switch 716 and the output of the FEM 700.

In yet another mode, if the output selector switch 710 selects the sixth input 714, then the input switch 716 couples signals applied to one of the input contacts 702, 704, 706 to the second output 720 of the switch 716 and the SPDT switch 724 couples the signal to sixth input of the output selector switch 710. This establishes a fourth bypass mode in which signals applied to one of the input contacts 702, 704, 706 can be routed to the output of the FEM 700 over a bypass path (i.e., without amplification by the FEM 700).

By providing the output selector switch 710 that can select from signals applied to the first three input connection points 202, 204, 206 or the second three contacts 702, 704, 706, the FEM 700 can provide the benefits of having a low noise figure, high gain path for critical signals applied to the first three inputs of the FEM 700. In addition, signals applied to these three inputs contacts 202, 204, 206 can be combined with each being amplified by a selected amount of gain. Since there is no input selector switch in the path prior to amplification of the signals, the noise figure is relatively low for signals that are routed through this path of the FEM 700. In addition, such critical signals can also follow a bypass path through the FEM 700 in which no amplification is applied.

However, providing the benefit of having a low noise figure on the high gain path requires one tank circuit 217 and one LNA 218, 230, 232 for each input. The inductors are typically relatively large. In contrast, providing three contacts 702, 704, 706 that use the same input inductor 116 and LNA 718 requires only one inductor (as opposed to 3 inductors for the three inputs) and one LNA 718 (as opposed to three LNAs for the three inputs). Such inputs can be used for signals for which it is not as important to have a low noise figure and the ability to combine signals. Therefore, the FEM 700 has the advantages of both a low noise figure FEM with the ability to combine some of the input signals, while still maintaining a relatively small size by having other inputs that share the same input inductor and LNA.

It should be noted that an FEM in accordance with the present disclosure can use any combination of inputs coupled to an input selector switch (such as the switch 716 of the FEM 700) and inputs coupled to tank circuits 217. The FEM 700 is one example in which the FEM 700 has 3 inputs coupled to an input selector switch 716 and three inputs coupled to tank circuits 217. Furthermore, all of the LNAs in an FEM in accordance with the disclosed method and apparatus can be implemented using any of the techniques noted above. That is, the claimed FEM is not limited by a particular LNA configuration, other than as expressly recited in the appended claims.

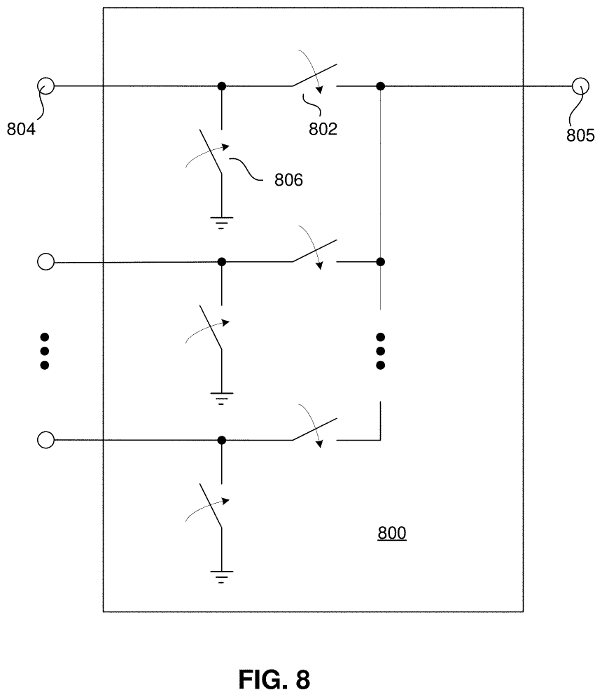

FIG. 8 is a simplified schematic of a selector switch 800. The selector switch 800 may be used as the output selector switch 210, 710 shown in the previous figures. In some embodiments, the switch 800 has a plurality of output switches 802, each corresponding to an associated input 804 and coupled between the associated input 804 and the switch output 805. The switch 800 also has a plurality of ground switches 806, each corresponding to an associated output switch 802 and input 804. Each ground switch 806 is coupled between the associated input 804 and ground. In some embodiments, only one output switch 802 is closed at any one time. In addition, only the ground switch 806 associated with the closed output switch 802 is open. All other ground switches 806 are closed. Therefore, any one (and only one) of the inputs 804 can be coupled to the output 805 at a time. All other inputs 804 are shunted to ground. In some embodiments, each of the switches 802, 806 are implemented using FETs.

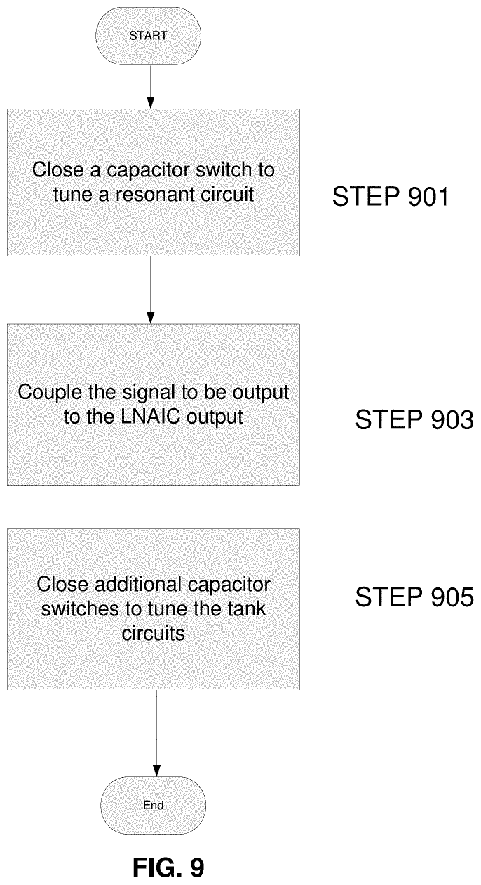

FIG. 9 is a flow diagram of a method in accordance with one disclosed embodiment. Referring to the FEM 200 shown in FIG. 2, one or more of the capacitor switches 214, 236, 238 are closed to tune the corresponding resonant circuit 217 to present a relatively high impedance between the FEM inputs 209, 213, 234 and the inputs of the corresponding amplifiers that are inactive (STEP 901). That is, if a signal presented to one of the inputs is to be coupled to the FEM output in bypass mode, then at least the tank circuit 217 associated with that input 209, 213, 234 is tuned to have a high impedance at the operational frequency. In addition, the input 220, 211, 225 of the output selector switch 210 corresponding with the FEM input 209, 213, 234 on which the signal is presented is selected to be coupled to the output 222 of the output selector switch 210, which in turn is coupled to the output connection point 235 of the LNAIC 201 and ultimately to the output 224 of the FEM 200 (STEP 903). In the case of an LNAIC 201 such as is shown in FIG. 2, having several LNAs 218, 230, 232, several tank circuits 217 may be tuned to have a relatively high impedance (i.e., capacitor switches 214, 236, 238 are closed) (STEP 905). Furthermore, in embodiments such as the LNAIC 301 shown in FIG. 3, there may be more than one capacitance switch 214, 258 that can be closed to tune the corresponding tank circuit 217 to have the optimal impedance at the operational frequency of the signal presented to the FEM inputs 209, 213, 234.

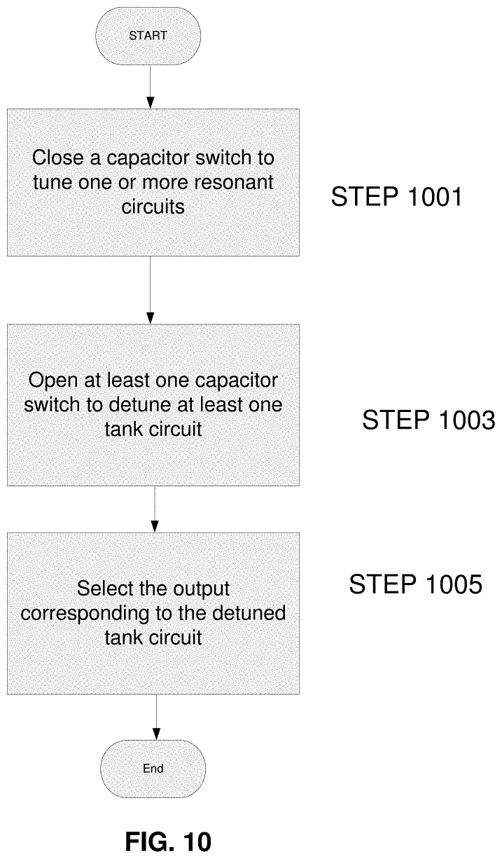

FIG. 10 is a flow diagram of a method in accordance with the disclosed embodiment in which at least one of the LNAs 218, 230, 232 is active. Those capacitor switches 214, 236, 238 corresponding to inactive LNAs 218, 230, 232 are closed (STEP 1001). However, any tank circuit 217 associated with an active LNA 218, 230, 232 is detuned by opening the corresponding capacitor switch 214, 236, 238 (STEP 1003). The output selector switch 210 selects the input 215 that is coupled to the outputs of the LNAs 218, 230, 232 (STEP 1005).

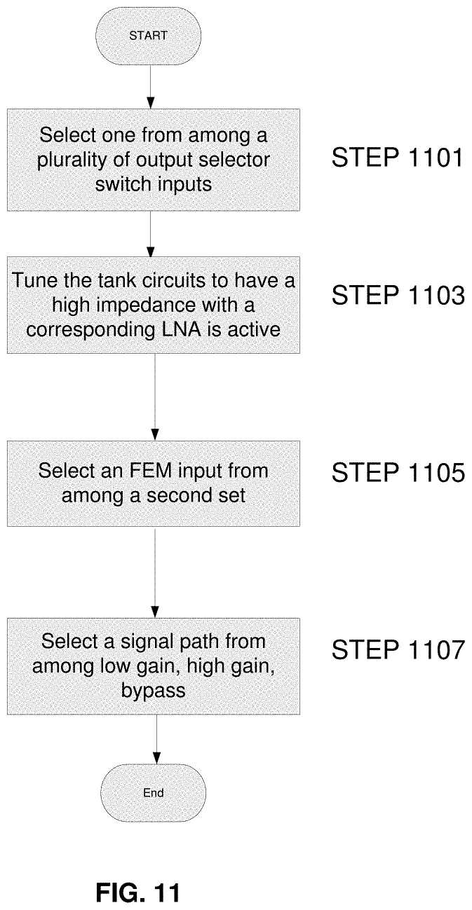

FIG. 11 is a flow diagram of a method in accordance with the disclosed embodiment in which the FEM 700 shown in FIG. 7 is used. The output selector switch 710 selects one from among several output selector switch inputs 712, 714, 728, 730, 732, 734 to be coupled to the FEM output 736 (STEP 1101). In the example shown in FIG. 7, four of the inputs 728, 730, 732, 734 to the output selector switch 710 are associated with FEM inputs 202, 204, 206 from a first set. Depending upon which input 728, 730, 732, 734 is selected, the tank circuits 217 are either tuned or detuned (STEP 1103). If either the input 712 or the input 714 are selected, then an FEM input is selected from a second set 702, 704, 706 (STEP 1105). In that case, a high/low gain switch 716 and an SPDT switch 724 determine which of the FEM inputs 702, 704, 706 are selected and whether the signals applied to those inputs traverse a high gain path, low gain path or bypass path (STEP 1107).

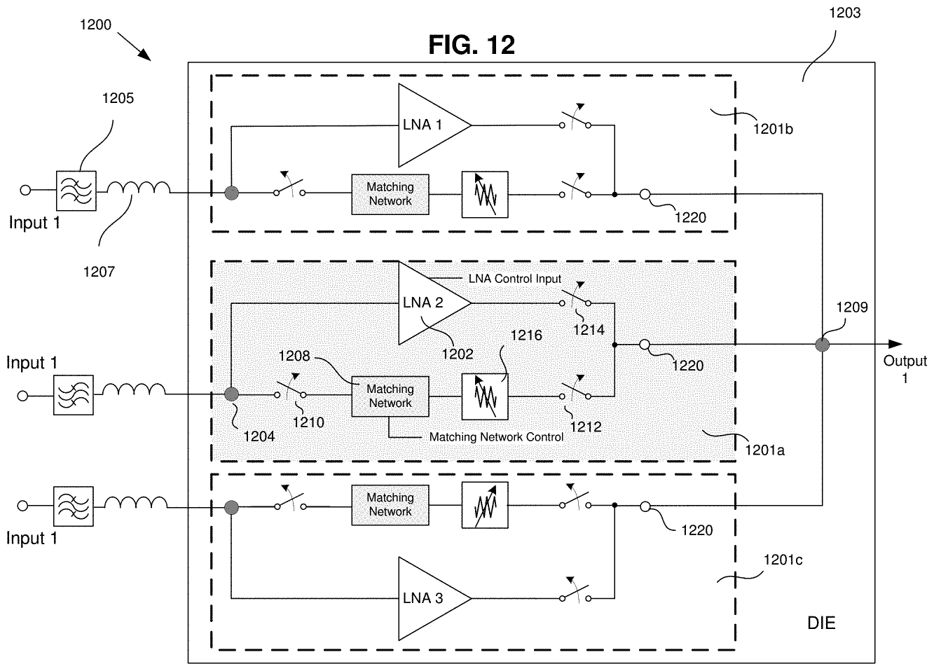

FIG. 12 is a simplified schematic of an FEM 1200 having a plurality of gain/bypass circuits 1201a, 1201b, 1201c. In some embodiments, each gain/bypass circuit 1201 may be fabricated on the substrate of an LNAIC 1203. In some such cases, all of the components of one gain/bypass circuit 1201 are fabricated on the one integrated circuit chip (or die) of one wafer and so reside on the same LNAIC 1203. In the embodiment shown in FIG. 12, three gain/bypass circuits 1201 are shown to be fabricated on the same LNAIC 1203. In other embodiments, more or less gain/bypass circuits 1201 may reside in the same LNAIC 1203. Alternatively, in some embodiments, various gain/bypass circuits 1201 are each fabricated on different integrated circuit chips (i.e., LNAICs). In some such embodiments, the LNAICs, may be mounted on one common substrate 1203 to form the FEM 1200. In alternative embodiments, each such LNAIC may have more than one gain/bypass circuit 1201 fabricated on it. Accordingly, it should be clear that any architecture of gain/bypass circuits can be used, regardless of how may gain/bypass circuits are fabricated together or are mounted on a common substrate to form a module.

Whether the gain/bypass circuits 1201 are fabricated on one LNAIC or several, additional components, such as filters 1205 and input inductors 1207 may be coupled to the gain/bypass circuits 1201 through gain/bypass circuit input 1204. In some embodiments, the gain/bypass circuit inputs 1204 are implemented with solder balls that provide a means by which the gain/bypass circuits 1201 can be physically and electrically connected to components, such as the inductors 1207, that are external to the gain/bypass circuits 1201. It should be noted that the configuration shown in FIG. 12 allows the input inductor and input signal to be coupled to the gain/bypass circuit 1201 through a single solder ball.

In the embodiment shown in FIG. 12 in which the three gain/bypass circuits 1201 are fabricated on a single LNAIC 1203, one solder ball 1209 provides a physical connection for a summed output of the three gain/bypass circuits 1201. The outputs may be summed similar to the outputs of the LNAs 502, 504, 506 discussed above with respect to FIG. 5. Alternatively, the outputs of each gain/bypass circuit 1201 may be summed through a summing circuit (not shown). The summing circuit may be a resistor network, matching network or other such network. The summing network may be either active or passive. Still further, rather than having bypass output switches 1212, the outputs of the matching networks 1208 of each gain/bypass circuit 1201 may be coupled through an output select switch, such as the switch 210 shown in FIG. 2.

The following is a description of the operation and architecture of one of the gain/bypass circuits 1201. In some embodiments, each of the gain/bypass circuits 1201 is essentially identical. Accordingly, the operation of only one is described here.

In accordance with some embodiments, the gain/bypass circuit 1201 comprises a low noise amplifier (LNA) 1202, a matching network 1208, an attenuator 1216, a gain/bypass input switch 1210, a bypass output switch 1212 and a gain mode output switch 1214. Alternatively, in some embodiments, the attenuator 1216 is not present. In some embodiments, the LNA 1202 is similar to, or the same as, the LNA 218 shown in FIG. 4.

The gain/bypass circuit input 1204 is coupled to the input of the LNA 1202 and to a first terminal of the bypass input switch 1210. A second terminal of the bypass input switch 1210 is coupled to the input of the matching network 1208. When the bypass input switch 1210 is closed, the first terminal is connected to the second terminal. Accordingly, the gain/bypass circuit input 1204 is coupled to the input of the matching network 1208 and to the input of the LNA 1202. A first terminal of the gain mode output switch 1214 is coupled to the output of the LNA 1202. A second terminal of the gain mode output switch 1214 is coupled to a gain/bypass circuit output 1220 and to a first terminal of the bypass output switch 1212. The second terminal of the bypass output switch 1212 is coupled to a first terminal of the attenuator 1216. A second terminal of the attenuator 1216 is coupled to the output of the matching network 1208. In embodiments in which there is no attenuator provided, the matching network 1208 is coupled directly to the bypass output switch 1212.

By closing the gain mode output switch 1214 and opening the bypass output switch 1212 and the bypass input switch 1210, the gain/bypass circuit is placed in gain mode. That is, the gain/bypass circuit input 1204 of the gain/bypass circuit 1201 is coupled to the input of the LNA 1202, which amplifies the input signal and outputs the amplified signal to the gain/bypass circuit output 1220. Since the bypass input switch 1210 is open in gain mode, the input impedance of the gain/bypass circuit 1201 is essentially determined by the input impedance of the active LNA 1202.

During bypass mode, the bypass input switch 1210 and the bypass output switch 1212 are both closed. The gain mode output switch 1214 is opened. In some embodiments, the LNA 1202 is turned off. That is, an LNA control input signal (such as the selection input signal coupled to the bias control module 414 shown in FIG. 4) is used to turn the LNA 1202 off. In some embodiments, the LNA control input signal causes the supply voltage to the LNA 1202 to be removed. Alternatively, the LNA 1202 remains on. Nonetheless, since the gain mode output switch is open, the LNA output is not terminated. Whether the LNA 1202 is turned off or not, the input impedance of the LNA 1202 changes when the gain mode output switch 1214 is open. The matching network 1208, which is coupled to the gain/bypass circuit input 1204, ensures that the impedance at the input 1204 is matched to the impedance looking into the attenuator 1216, such that any change in the input impedance of the gain/bypass circuit 1201 is maintained within an acceptable tolerance. In some cases, the matching network can be tuned such that the difference between the input impedance during gain mode and during bypass mode is negligible.

In accordance with some embodiments, the matching network 1208 can be particularly tuned to the frequency range of the input signals that are to be applied to the gain/bypass circuit 1201. A matching network control signal applied to the matching network 1208 is used to control the input impedance of the matching network 1208. In some embodiments, the attenuator 1216 is variable. That is, the amount of attenuation can be dynamically adjusted to set the level of the output signal during bypass mode.

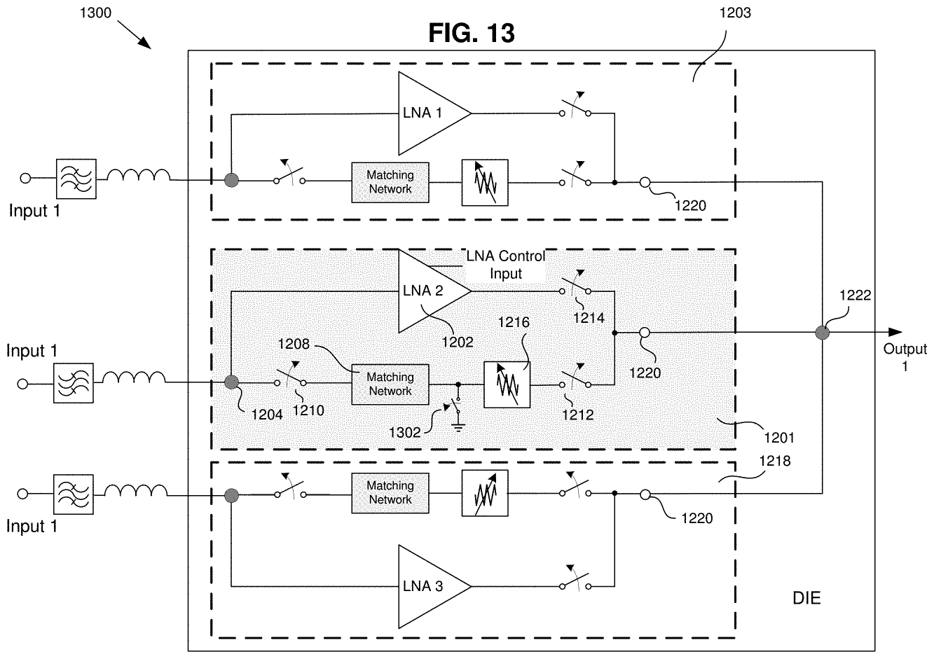

FIG. 13 is a simplified schematic of an FEM 1300 similar to that of FIG. 12, however, a matching network shunt switch 1302 is provided that is coupled to the output of the matching network 1208 to shunt the output of the matching network 1208 to ground (or another fixed potential). In the embodiment of FIG. 13, the bypass input switch 1210 can be closed during gain mode to allow the matching network to be used to adjust the input impedance of the gain/bypass circuit 1201. In some embodiments, this might be done in order to tune the input impedance for different input frequency ranges. When operating in gain mode, the bypass input switch 1210 is closed, but the bypass output switch 1212 is open and the matching network shunt switch 1302 is closed, providing the ability to tune the input impedance of the gain/bypass circuit 1201 in the gain mode by adjusting the input impedance of the matching network 1208.

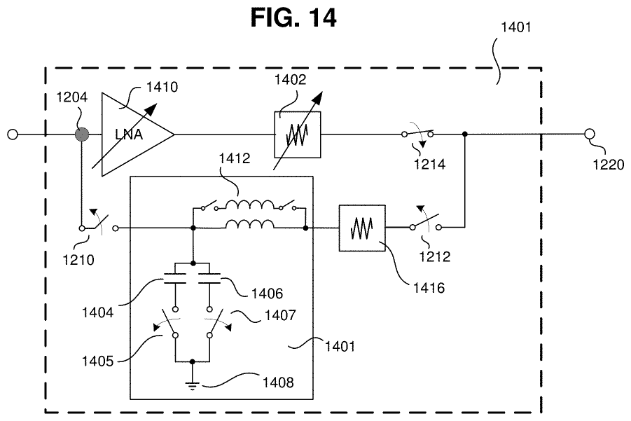

FIG. 14 is a simplified schematic of yet another embodiment of the disclosed apparatus. A matching network 1401 comprises shunt capacitors 1404, 1406 in parallel. Each of the shunt capacitors 1404, 1406 are coupled to ground through a unique one of two switches 1405, 1407. Accordingly, the amount of shunt capacitance can be selected. While FIG. 14 shows two such shunt capacitors 1404, 1406, any number of capacitors and associated switches can be included to provide the desired flexibility in selecting the amount of shunt capacitance, and thus provide the desired control over the input impedance. Similarly, a selectable series inductance 1412 can be provided between the input of the matching network 1401 and the output of the matching network 1401. In some embodiments, only one inductor 1412 is provided, limiting the number of switches provided within the matching network 1401. In addition, in some embodiments, an attenuator 1402 is provided at the output of the LNA 1410. Furthermore, the attenuator 1416 may be either fixed or variable. Still further, the LNA 1410 may be either a fixed gain or variable gain LNA.

It will be clear to those of ordinary skill in the art that different matching topologies can be used based on the requirements (e.g., size, low pass, high pass, tunability, etc.). By providing a matching network 1208 that improves the S11 parameter at the input of the gain/bypass circuit 1201, the number of switches required is reduced. In particular, the number of switches required at the input of the LNA 1202 is reduced, thus improving the noise figure of the gain/bypass circuit in gain mode. That is, by removing the switch at the input of the LNA 1202, the loss to signal prior to being amplified by the LNA 1202 is reduced. In some cases, this architecture results in a noise figure of approximately 0.8 dB at 4 GHz, as opposed to a noise figure of approximately 1.1 dB at 4 GHz for alternative architectures in which the input signal passes through a switch prior to being amplified by the LNA.

As should be readily apparent to one of ordinary skill in the art, various embodiments of the invention can be implemented to meet a wide variety of specifications. Thus, selection of suitable component values is a matter of design choice (so long as the frequencies of interest mentioned above can be handled). The switching and passive elements may be implemented in any suitable integrated circuit (IC) technology, including but not limited to MOSFET and IGFET structures. Integrated circuit embodiments may be fabricated using any suitable substrates and processes, including but not limited to standard bulk silicon, silicon-on-insulator (SOI), silicon-on-sapphire (SOS), GaAs pHEMT, and MESFET processes. Voltage levels may be adjusted or voltage polarities reversed depending on a particular specification and/or implementing technology (e.g., NMOS, PMOS, or CMOS). Component voltage, current, and power handling capabilities may be adapted as needed, for example, by adjusting device sizes, “stacking” components to handle greater voltages, and/or using multiple components in parallel to handle greater currents. In addition, components, such as capacitors and inductors, etc., while shown as one component, may be implemented as several components that are grouped and switchable to provide digitally selectable component values.

A number of embodiments have been described. It is to be understood that various modifications may be made without departing from the spirit and scope of the claimed invention. For example, some of the steps described above may be order independent, and thus can be performed in an order different from that described. It is to be understood that the foregoing description is intended to illustrate and not to limit the scope of the invention, which is defined by the scope of the following claims, and that other embodiments are within the scope of the claims.

What is claimed is:

1. A gain/bypass circuit comprising:
(a) a low noise amplifier (LNA) directly coupled to a gain/bypass circuit input and selectively coupled to a gain/bypass circuit output; and
(b) a matching network selectively coupled to the gain/bypass circuit input and selectively coupled to a gain/bypass circuit output, wherein the input impedance of the matching network is such that the impedance at the gain/bypass circuit input in bypass mode is within a desired tolerance of the impedance at the gain/bypass circuit input in gain mode;
wherein in bypass mode the matching network is coupled to the gain/bypass circuit input and to the gain/bypass circuit output and the LNA output is disconnected from the gain/bypass circuit output; and
wherein in gain mode, the matching network is disconnected from the gain/bypass circuit input and the gain/bypass circuit output and the LNA output is connected to the gain/bypass circuit output.

2. The gain/bypass circuit of claim 1, wherein the impedance of the matching network is selectable.

3. The gain/bypass circuit of claim 2, wherein the matching network comprises a tunable shunt capacitance.

4. The gain/bypass circuit of claim 2, wherein the matching network comprises a tunable series inductance.

5. A front end module (FEM), including:
(a) an gain/bypass circuit input;
(b) a bypass input switch having a first and second terminal, the first terminal coupled to the gain/bypass circuit input;
(c) a bypass output switch having a first and second terminal;
(d) a gain mode output switch having a first and second terminal, the second terminal of the gain mode output switch coupled to the second terminal of the bypass output switch;
(e) an amplifier having an amplifier input and an amplifier output, the amplifier input coupled directly to the gain/bypass circuit input and the amplifier output coupled to the first terminal of the gain mode output switch; and
(f) an input matching circuit having a first terminal coupled to the second terminal of the bypass input switch, and having a second terminal coupled to the first terminal of the bypass output switch, the input matching circuit having an impedance such that the impedance at the gain/bypass circuit input in bypass mode is within a desired tolerance of the impedance at the gain/bypass circuit input in gain mode.

6. The FEM of claim 5, wherein the impedance of the input matching circuit is selectable.

7. The FEM of claim 5, further including a variable attenuator placed in the bypass path.

8. The FEM of claim 5, further including a variable attenuator placed at the output of the amplifier.

9. The FEM of claim 5, wherein the input matching network comprises a first and second capacitive element coupled in parallel between the second terminal of the bypass input switch and a reference point.

10. The FEM of claim 5, wherein the amplifier is a variable gain low noise amplifier (LNA).

11. The FEM of claim 5, wherein the gain/bypass circuit input, the bypass input switch, the bypass output switch, the gain mode output switch and the input matching circuit comprise a first gain/bypass circuit, the FEM further including at least a second gain/bypass circuit, each gain/bypass circuit having an gain/bypass circuit output.

12. The FEM of claim 11, at least two of the gain/bypass circuit outputs being coupled together such that controlling the bypass output switch and gain mode output switch within each gain/bypass circuit allows one of more gain/bypass circuits to be selectively coupled to an FEM output.

13. The FEM of claim 12, wherein the output selector switch can selectively couple combinations of two or more of the gain/bypass circuit outputs together at the output of the output selector switch.

14. The FEM of claim 5, wherein the amplifier has an LNA control input terminal to receive an LNA control input signal for turning the amplifier on and off.

15. The FEM of claim 5, wherein the input matching circuit can be selectively tuned for operation in one of a plurality of operating frequency ranges.

16. The FEM of claim 5, wherein the gain/bypass circuit input, the bypass input switch, the gain mode output switch and the input matching circuit comprise a first gain/bypass circuit fabricated on a single die having one connection terminal coupled to the gain/bypass circuit input and one output terminal coupled to an FEM output.

17. The FEM of claim 5, wherein the gain/bypass circuit further includes a matching network shunt switch at the output of the matching network and wherein the impedance of the matching circuit can be tuned to establish a desired input impedance for a desired operating frequency when the matching network shunt switch is closed, the bypass input switch is closed, the bypass output switch is open and the gain mode output switch is closed.
